(19) United States
(12) Patent Application Publication
(10) Pub. No.: US 2006/0065932 A1
(43) Pub. Date: Mar. 30, 2006

(54) Circuit to improve ESD performance made by fully silicided process

(75) Inventors: Shao-Chang Huang, Hsinchu City (TW); Yu-Hung Chu, Guanxi Town (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd.

(21) Appl. No.: 10/956,315

(22) Filed: Sep. 30, 2004

(51) Int. Cl. H01L 31/111

(52) U.S. Cl. 257/355

(57) ABSTRACT

An electrostatic discharge (ESD) protection circuit is provided. The circuit is coupled between a first and a second node for dissipating an ESD current. The circuit comprises a first transistor formed on a substrate with its gate and a first diffusion region coupled to the first node for receiving the ESD current, and a second transistor coupled in series with the first transistor at its second diffusion region and with the second transistor's gate coupled to the second node for dissipating the ESD current therethrough, wherein the first transistor provides a N/P junction close to its diffusion regions for directing the ESD current through a parasitic transistor in the substrate and the second transistor.

### BACKGROUND

The present invention relates generally to integrated circuit designs; and more particularly, to a method to improve electrostatic discharge (ESD) performance on fully silicided process.

The gate oxide of a metal-oxide-semiconductor (MOS) transistor of an integrated circuit (IC) is most susceptible to damage. The gate oxide may be destroyed by being contacted with a voltage only a few volts higher than the supply voltage. It is understood that a regular supply voltage in an integrated circuit is 5.0, 3.3 volts or even lower. Electrostatic voltages from common environmental sources can easily reach thousands, or even tens of thousands of volts. Such voltages are destructive even though the charge and any resulting current are extremely small. For this reason, it is of critical importance to discharge any static electric charge, as it builds up, before it accumulates to a damaging voltage.

ESD protection circuit is typically added to ICs at the bond pads. The pads are the connections to the IC, to outside circuitry, for all electric power supplies, electric grounds, and electronic signals. Such added circuitry must allow the normal operation of the IC. That means that the protective circuitry is effectively isolated from the normally operating core circuitry because it blocks current flow through itself. In an operating IC, electric power is supplied to a VCC pad, electric ground is supplied to a VSS pad, electronic signals are supplied from outside to some pads, and electronic signals generated by the core circuitry of the IC are supplied to other pads for delivery to external circuits and devices. In an isolated, unconnected IC, all pads are considered to be electrically floating, or of indeterminate voltage.

ESD can arrive at any pad. This can happen, for example, when a person touches some of the pads on the IC. This is the same static electricity that may be painfully experienced by a person who walks across a carpet on a dry day and then touches a grounded metal object. In an isolated IC, ESD acts as a brief power supply for one or more pads, while the other pads remain floating, or grounded. Because the other pads are grounded, when ESD acts as a power supply at a randomly selected pad, the protection circuitry acts differently than it does when the IC is operating normally. When an ESD event occurs, the protection circuitry must quickly become conductive so that the electrostatic charge is conducted to VSS or ground and dissipated before any damaging voltage may build up.

As technology shrinks in size and components of IC become more sensitive to large voltage of ESD pulses, however, quicker dissipation of the harmful ESD charges is necessary. In order to speed up the IC, silicide has been widely used as a contact material for source, drain, gate electrodes, and interconnections to realize the high-speed operation of submicron complementary metal-oxide-semiconductor (CMOS) logic circuits. In addition to improved speed, another advantage of implementing silicide into ESD protection circuits is a decrease in physical size of the transistors without downgrading ESD performance.

While silicides can both provide ESD protection circuits with a faster contact and interconnect material, and decrease the physical size of the circuit, it also makes components within an ESD protection circuit extremely sensitive to the high voltage and heat created from an ESD event. Source and drain punch through implemented with silicide is easy to happen at higher voltage. A non-protected transistor can be damaged in a short amount of time when the heat created by an ESD pulse begins to rise. To solve this problem, conventional methods typically implement extra ESD implant and silicide blocking layers to protect the transistor, but these additions increase the size, require additional masks, affect product yield, and slow down the ESD dissipation process.

Desirable in the art of IC design are additional designs and methods that compensate the side effects of silicide without degrading overall ESD performance.

### SUMMARY

In view of the foregoing, this invention provides a method for improving ESD performance of an ESD protection circuit with fully silicided process. In order to protect the ESD protection transistor from harmful ESD pulses during an ESD event, additional transistors are implemented to replace the needs of extra silicide blocking layers. By implementing additional transistors, additional masks for the ESD implant layer and the silicide blocking layer are not necessary.

In several embodiments of the present invention, ESD protection circuits made from a fully silicide process is provided. The circuit is coupled between a first and a second node for dissipating an ESD current. The circuit comprises a first transistor formed on a substrate with its gate and a first diffusion region coupled to the first node for receiving the ESD current, and a second transistor coupled in series with the first transistor at its second diffusion region and with the second transistor's gate coupled to the second node for dissipating the ESD current therethrough, wherein the first transistor provides a N/P junction close to its diffusion regions for directing the ESD current through a parasitic transistor in the substrate and the second transistor.

Along with these embodiments of the present invention, ESD protection circuits can be improved by fine tuning the trigger voltage of the circuit, thereby allowing faster ESD charge dissipation during an ESD event.

The construction and method of operation of the invention, however, together with additional objects and advantages thereof will be best understood from the following descriptions of specific embodiments when read in connection with the accompanying figures.

### BRIEF DESCRIPTION OF THE DRAWINGS

FIG. 1 illustrates a conventional grounded-gate NMOS transistor ESD protection circuit.

FIG. 2 illustrates another conventional grounded-gate NMOS transistor ESD protection circuit implemented with another stacked NMOS transistor.

FIGS. 3A-3B illustrate a grounded-gate NMOS transistor ESD protection circuit implemented with an additional stacked NMOS transistor where the gate is tied to the output pad through a resistor in accordance with the first embodiment of the present invention.

FIGS. 4A-4B illustrate a grounded-gate NMOS transistor ESD protection circuit implemented with a stacked NMOS transistor with a floating gate in accordance with the second embodiment of the present invention.

FIGS. 5A-5B illustrate a grounded-gate NMOS transistor ESD protection circuit implemented with two additional stacked NMOS transistors in accordance with the third embodiment of the present invention.

FIGS. 6A-6B illustrate a grounded-gate NMOS transistor ESD protection circuit implemented with multiple additional stacked NMOS transistors in accordance with the fourth embodiment of the present invention.

FIG. 7 illustrates PMOS transistor ESD protection circuit in accordance with an embodiment of the present invention.

### DESCRIPTION

The present invention provides methods and circuits for compensating the side effects of silicide without degrading overall ESD performance.

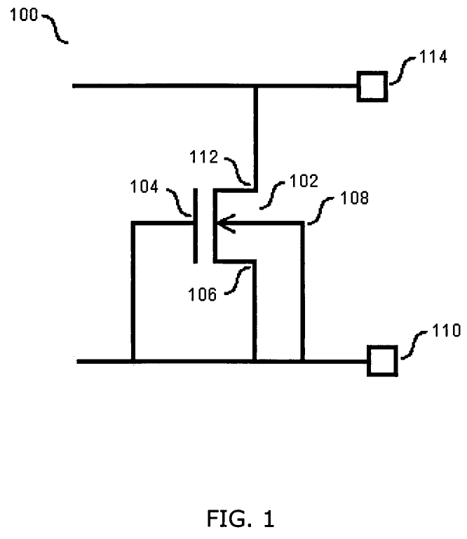

FIG. 1 illustrates a conventional grounded-gate NMOS transistor ESD protection circuit 100, which provides ESD protection to an IC circuitry by utilizing a grounded-gate NMOS 102 to provide a path for the discharge of ESD charges. The protection circuit 100 is placed in parallel with the IC circuitry that is to be protected from an ESD event. A gate 104, a source 106, and a P-type substrate 108 of the NMOS 102 are all coupled together, and led to a pad 110, which typically is VSS ground. A drain 112 of the NMOS 102 is tied to an output pad 114 of the IC circuitry such that the protection circuit 100 can protect the IC by drawing ESD current to the pad 110, or VSS ground, when the NMOS 102 turns on during an ESD event.

The protection circuit 100 functions in two modes of operation: normal operation mode and ESD mode. In normal operation mode, source supply applies power to VDD and VSS lines of the IC. As such, the voltage at the operating pad 114 is permitted to vary between VDD and VSS. Because the gate 104 is grounded, the NMOS 102 will remain off. This allows normal operation of the IC since the output pad 114 is free to respond to normal circuit conditions.

When an ESD event occurs, the incoming voltage at the output pad 114 will be significantly higher than VDD with respect to VSS. This will cause the drain-source voltage of the NMOS 102 to increase rapidly above VDD voltage. The reverse bias voltage on the PN junction formed between the drain 112 and the P− type substrate 108 will be increased by the large voltage at the drain 112 of the NMOS 102. When the reverse bias voltage reaches a point where the reverse bias junction undergoes a breakdown, current will flow between the drain 112 and the source 106. The NMOS 102, therefore, allows dissipation of ESD current to the pad 110, or VSS ground, before harmful charges build up to damage the IC.

However, this conventional method can only provide protection for ICs that utilize a certain fixed supply voltage. In many cases, this fixed voltage can be either too large or too small for the application. Due to the lack of silicide in this conventional method, physical size of the circuit may be very large.

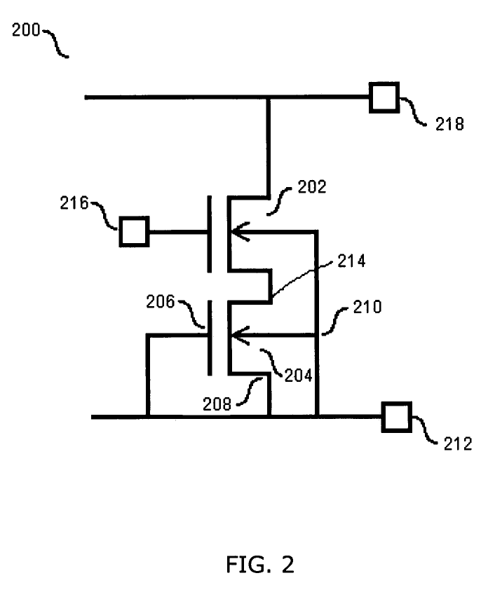

FIG. 2 illustrates another conventional grounded-gate NMOS transistor ESD protection circuit 200 with a stacked NMOS 202 implemented for higher voltage tolerance. The protection circuit 200 provides ESD protection to an IC circuitry by utilizing a grounded-gate NMOS 204 to provide a path for the discharge of ESD charges. The protection circuit 200 is placed in parallel with the IC circuitry that is to be protected from an ESD event. A gate 206, a source 208, and a P-type substrate 210 of the NMOS 204 are all tied together, and led to a pad 212, which is typically VSS ground. A drain 214 of the NMOS 204 is tied to the source of the NMOS 202. The NMOS 202, whose gate is directly connected to a pad 216, which may further be connected to supply VCC, will be turned on during normal operation to provide a voltage drop to help protect the NMOS 204 from voltage stress. The drain of the NMOS 202 is tied to an output pad 218 of the IC circuitry such that the protection circuit 200 can protect the IC by drawing ESD current to VSS ground when the NMOS 204 turns on during an ESD event.

The protection circuit 200 functions in two modes of operation: normal operation mode and ESD mode. In normal operation mode, the source supply applies power to the output pad 218. As such, the voltage at the output pad 218 is permitted to vary between VDD and VSS. Because the gate 206 is grounded, the NMOS 204 will remain off during normal operation of the IC. This allows the IC to operate normally since the output pad 218 is free to respond to normal circuit conditions.

When an ESD event occurs, the incoming voltage at the output pad 218 will be significantly higher than VDD with respect to VSS ground. This will cause the drain-source voltage of the NMOS 204 to increase rapidly above normal operating voltage. The reverse bias voltage on the PN junction formed between the drain 214 and the P-type substrate 210 of the NMOS 204 will be increased by the large voltage at the drain 214 of the NMOS 204. When the reverse bias voltage reaches a point where the reverse bias junction undergoes a breakdown, current will flow between the drain 214 and the source 208. The NMOS 202, whose gate is tied to the pad 216, or supply VCC, will be left open during an ESD event. As such, it only acts as a resistance to limit the harmful ESD current flow to the drain 214 of the NMOS 204. The NMOS 204, which by now is conducting, will dissipate ESD current to the pad 212, or VSS ground, before harmful charges build up to damage the IC.

However, it is understood that transistors depicted in FIG. 2, if implemented without silicide, will be very large in size and may not be practical in submicron technologies. More specifically, in deep sub-micron process for example, big resistor protection oxide (RPO) regions have to be created and additional ESD implants have to be made. Both the RPO and additional ESD implants require additional masks to complete the manufacturing which adds extra cost and reduces the efficiency to the overall manufacturing process.

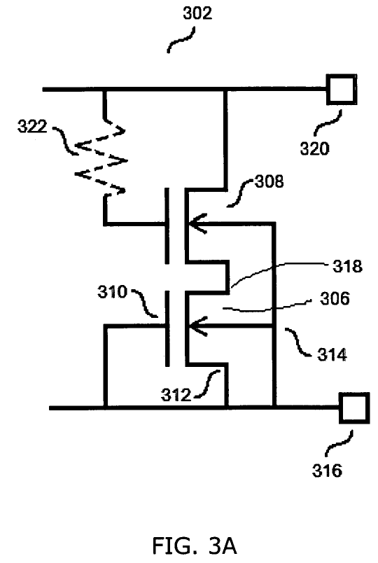

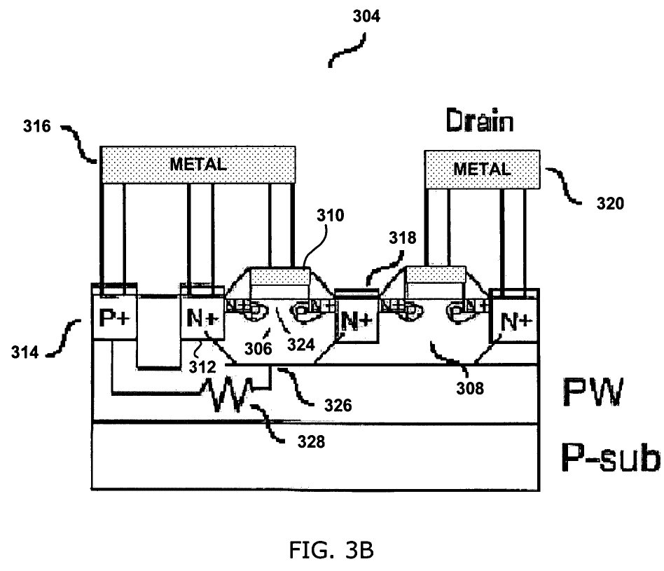

FIGS. 3A and 3B illustrate a grounded-gate NMOS transistor ESD protection circuit 302 and its cross-sectional view 304, respectively, in accordance with the first embodiment of the present invention. The protection circuit 302 provides ESD protection to an IC circuitry by utilizing a grounded-gate, silicided NMOS 306 to provide a path for the discharge of ESD charges. A NMOS 308 is in a stack formation along with the NMOS 306, and acts as a resistor protection oxide (RPO) to provide higher voltage tolerance to protect the NMOS 306 from harmful ESD pulses. The NMOS 308 also creates a voltage drop, thereby allowing a variety of supply voltages to be used. The NMOS 308 can be a native device. The protection circuit 302 is placed in parallel with the IC circuitry that is to be protected from an ESD event. A gate 310, a source 312, and a P-type substrate 314 of the NMOS 306 are all coupled to a pad 316, which is typically VSS ground. A drain 318 of the NMOS 306 is tied to the source of the NMOS 308, while the drain of the NMOS 308 is connected to an output pad 320 of the IC circuitry. The function of the NMOS 308 is similar to an RPO module for preventing an ESD current to go through a silicided surface of the substrate. By using this NMOS 308, no additional RPO or ESD implants are needed since the device is formed just like any other transistors in the standard process. The NMOS 308 can be a zero-threshold device so that a better performance may be obtained in a normal operation of the circuit. With the gate of the NMOS 308 directly connected to the circuit pad 320 (or through an optional resistor 322), the NMOS 308 will be turned on automatically when an ESD event occurs, thereby allowing the protection circuit 302 to protect the IC by drawing ESD current to VSS ground when the NMOS 306 turns on. When the resistor 322 is implemented, it is to protect the sensitive gate oxide of the NMOS 308 from the large voltage stress during an ESD event. Although not shown, in some embodiments, both the transistors 306 and 308 can be thick oxide devices.

The cross-sectional view 304 shows the parasitic equivalent of both NMOSs 306 and 308. Both the drain 318 and the source 312 of the NMOS 306 are represented by N+ diffusions. The P-type substrate 314, the source 312, and the gate 310 are all tied to metal that leads to the pad 316, or VSS ground. At the gate 310, there is a channel region 324 that is set between the N+ diffusions of the drain 318 and the source 312. This channel region 324 conducts the drain-source current which is needed in order to dissipate ESD charges during an ESD event. The collector of a parasitic lateral NPN transistor 326 is shown to be connected to the drain 318 of the NMOS 306 and the drain of the NMOS 308, while the emitter of the parasitic lateral NPN transistor 326 is connected to the source 312 of the NMOS 306. The base of the parasitic lateral NPN transistor 326 is connected to the P-type substrate 314 through a substrate resistance 328. Gate and N type drains of NMOS 308 are all tied to metal that leads to output pad 320 which is connected to the IC.

Further, it is noticed that at the source and drain ends of the transistor 308, there are N+ LDD region and P− pockets formed for preventing punch through. On the transistor 306 side, N+ LDD region and P− pockets are also formed. The N+ LDD region and the P− pocket forms a zenor diode which will more effectively direct the ESD current to the substrate and further dissipates through a parasitic bipolar transistor 328. As such, this thin oxide transistor 308 provides a N/P junction structure (or more accurately in this configuration, a N+/P− junction), which functions as a normal ESD implant region to direct the ESD current along with the transistor 306. From the perspective of device manufacturing, the formation of the transistor 308 fully conforms with the current standard manufacturing process. As such, the formation of the N/P junction structure does not require any additional special masks, thereby improving the efficiency and reducing the cost for forming such devices.

In normal operation mode, source supply applies power to the output pad 320. As such, the voltage at the output pad 320 is permitted to vary between VDD and VSS ground. With voltage at the output pad 320, the NMOS 308 will be turned on, but because the gate 310 of the NMOS 306 is grounded, the NMOS 306 will remain off. This allows normal operation for the IC since the output pad 320 is free to respond to normal circuit conditions.

During an ESD event, the incoming voltage at the output pad 320 will be significantly higher than VDD with respect to VSS. The NMOS 308 will protect the NMOS 306 by providing some resistance to limit the current going through the channel of the NMOS 306. By having the NMOS 308 taking a share of the heat created from the ESD pulses, the NMOS 306 may operate normally during the ESD event. The high voltage will cause the drain-source voltage of the NMOS 306 to increase rapidly above the normal operating voltage. The reverse bias voltage on the PN junction formed between the drain 318 and the P-type substrate 314 will be increased by the large voltage at the drain of the NMOS 306. When the reverse bias voltage reaches a point where the reverse bias junction undergoes a breakdown, current will flow between the drain 318 and the source 312. This will cause the PN junction between the channel region 324 and the source 312 to become forward biased, thereby forcing the parasitic lateral NPN transistor 326 to conduct. The NMOS 306 dissipates ESD current to the pad 316, or VSS ground, before harmful charges build up to damage the IC.

With this configuration, it is not necessary to have additional silicide blocking masks since the NMOS 308 can perform as a current limiting device. This invention can also improve the use of native devices or devices with zero threshold voltage, thereby allowing better normal low voltage operation.

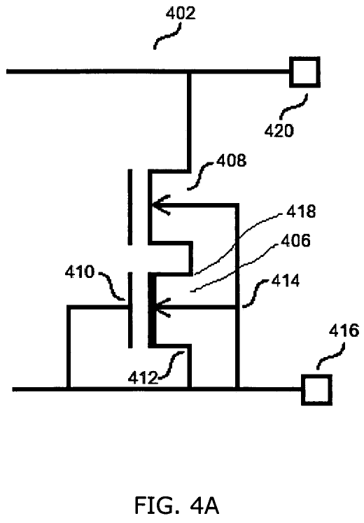

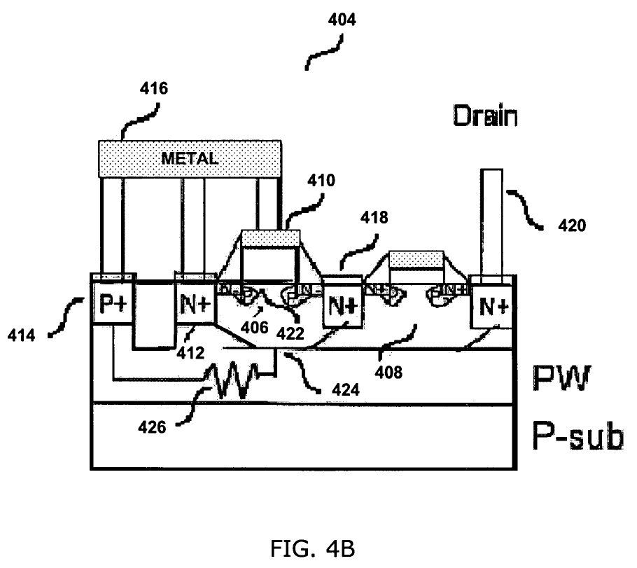

FIGS. 4A and 4B illustrate a grounded-gate NMOS transistor ESD protection circuit 402 and its cross-sectional view 404, respectively, in accordance with the second embodiment of the present invention. The protection circuit 402 provides ESD protection to an IC circuitry by utilizing a grounded-gate, silicided thick-oxide NMOS 406 to provide a path for the discharge of ESD charges. A silicided, thin-oxide NMOS 408, which is in a stack formation along with the NMOS 406, provides some resistance such that the protection circuit 402 may have a higher voltage tolerance. The protection circuit 402 is placed in parallel with the IC circuitry that is to be protected from an ESD event. A gate 410, a source 412, and a P-type substrate 414 of the NMOS 406 are all tied together, and led to a pad 416, which is typically VSS ground. A drain 418 of the NMOS 406 is tied to the source of the NMOS 408, and the drain of the NMOS 408 is connected to an output pad 420 of the IC circuitry. The gate of the NMOS 408 is left floating to provide more resistance to protect the PN junction of the NMOS 406. The NMOS 408, whose gate is floating, serves as another form of current blocking device between the pad 420 and the NMOS 406. The NMOS 408 also creates a voltage drop, which makes the protection circuit 402 more versatile by allowing a higher supply voltage to be used.

The cross-sectional view 404 shows the parasitic equivalent of both NMOSs 406 and 408. Both the drain 418 and the source 412 of the NMOS 406 are represented by N+ diffusions. The P-type substrate 414, the source 412, and the gate 410 are all tied to metal leading to the pad 416, or VSS ground. At the gate 410 of the NMOS 406, there is a channel region 422 that is set between the N+ diffusions of the drain 418 and the source 412. This channel region 422 conducts the drain-source current during an ESD event. The collector of a parasitic lateral NPN transistor 424 is shown to be connected to the drain 418 of the NMOS 406 and the drain of the NMOS 408, while the emitter of the parasitic lateral NPN transistor 424 is connected to the source 412 of the NMOS 406. The base of the parasitic lateral NPN transistor 424 is connected to the P-type substrate 414 through a substrate resistance 426. The NMOS 408 is left floating with its gate unconnected, while its drain is connected to the output pad 420. As it is shown, the thin oxide transistor 408 co-exist with the thick oxide transistor 406, and the thin oxide transistor 408 has the function of an RPO. Further, it is noticed that at the source and drain ends of the transistor 408, there are N+ LDD region and P− pockets formed for preventing punch through as the device is getting small. On the thick oxide transistor 406 side, N− LDD region and P− pockets are also formed. The N+ LDD region and the P− pocket closer to the drain 420 will more effectively direct the ESD current to the substrate and further dissipated through a parasitic bipolar transistor. As such, this thin oxide transistor 408 provides a N+/P− junction which functions as a normal ESD implant region to direct the ESD current along with the thick oxide transistor 406. The thin oxide transistor 408 with its gate floating can also sustain more ESD charges than a transistor with its gate connected to a regular voltage. From the perspective of device manufacturing, the formation of the thin oxide transistor 408 fully conforms with the current standard manufacturing process. As such, the formation of the N+/P− junction does not require any additional special masks, thereby improving the efficiency and reducing the cost for forming such devices. It is also understood that the transistor 406 is shown as a thick oxide device, but it does not have to. As long as it can sustain ESD charges in certain designs, a thin oxide transistor can be placed there as well. Furthermore, the distance between the drains of the transistor 408 and the transistor 406 is most likely between 35 nm to 35 micro meter.

In normal operation mode, source supply applies power to the output pad 420. As such, the voltage at the output pad 420 is permitted to vary between VDD and VSS. At this point, the NMOS 408 essentially acts as a charge-coupled diffusion resistor limiting the current flow to the drain 418 of the NMOS 406. However, since the gate 410 of the NMOS 406 is grounded, the NMOS 406 will remain off. This allows normal operation for the IC since the output pad 420 is free to respond to normal circuit conditions.

When an ESD event occurs, the incoming voltage at the output pad 420 will be significantly higher than VDD with respect to VSS. The NMOS 408, which is charge-coupled, will provide some protection for the NMOS 406 from the ESD charges by limiting current flow to the channel of the NMOS 406. By having the NMOS 408 taking a share of the heat created from the ESD pulses, the NMOS 406 may operate normally during the ESD event. The high voltage of ESD pulses will cause the drain-source voltage of the NMOS 406 to increase rapidly above normal operating voltage. The reverse bias voltage on the PN junction formed between the drain 418 and the P-type substrate 414 will be increased by the large voltage at the drain 418 of the NMOS 406. When the reverse bias voltage reaches a point where the reverse bias junction undergoes a breakdown, current will flow between the drain 418 and the source 412. This will cause the PN junction between the channel region 422 and the source 412 to become forward biased, thereby forcing the parasitic lateral NPN transistor 424 to conduct. The NMOS 406 dissipates the ESD current to the pad 416, or VSS ground, before harmful charges build up to damage the IC.

Since the NMOS 408 provides a more robust resistance to protect the NMOS 406, the NMOS 406 can be either a thick or thin NMOS.

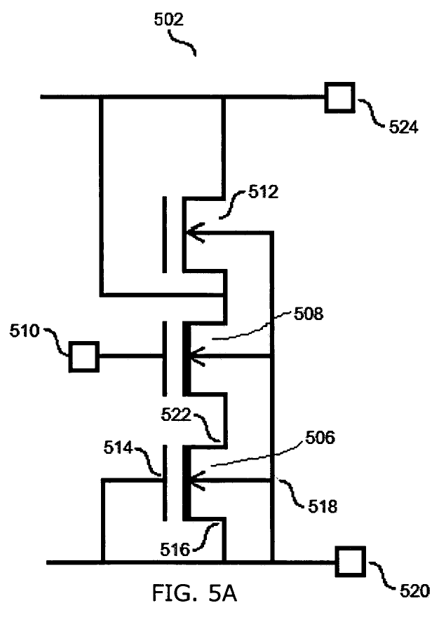

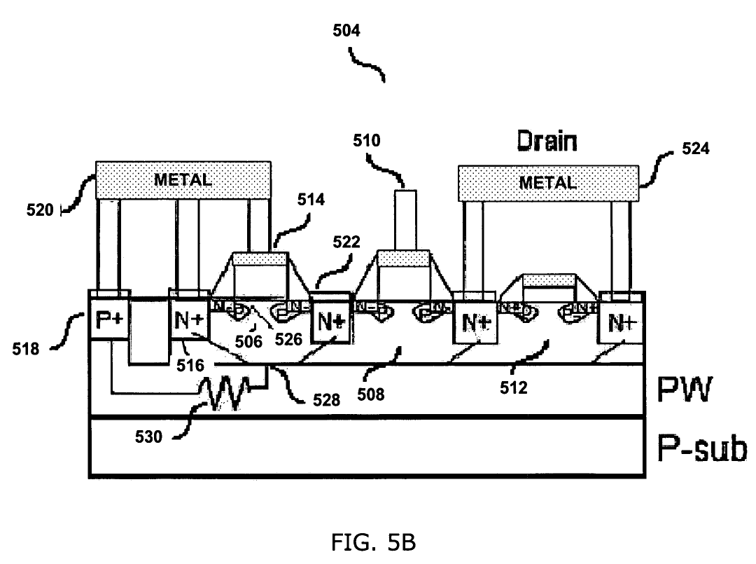

FIGS. 5A and 5B illustrate a grounded-gate NMOS transistor ESD protection circuit 502 and its cross-sectional view 504, respectively, in accordance with the third embodiment of the present invention.

The protection circuit 502 provides ESD protection to an IC circuitry by utilizing a grounded-gate, silicided, thick-oxide NMOS 506 to provide a path for the discharge of ESD charges. The protection circuit 502 is placed in parallel with the IC circuitry that is to be protected from an ESD event. The NMOS 508, being a thick oxide high threshold voltage transistor and a resistance spacer or silicide blocker, is in a stack formation along with a floating-gate, thin-oxide NMOS 512 to provide protection for the NMOS 506 by limiting the current flow to the NMOS 506. In order to differentiate the NMOS 508 from the gate grounded NMOS 506, the NMOS 508 may be referred to as a blocking thick oxide transistor. However, since the gate of the NMOS 508 is tied to a pad 510, or a supply VCC, a base widening issue may occur when the supply VCC is floating during an ESD event. Instead of adding ESD implants to compensate the issue, the NMOS 512 is implemented along with the NMOS 508 in a stack formation to create a PN junction. By implementing the NMOS 512, more resistance is added to protect the NMOS 506 during an ESD event. Since the floating gate of the NMOS 512 can be charge-coupled, there will be no thin-oxide issues. A gate 514, a source 516, and a P-type substrate 518 of the NMOS 506 are all tied together, and led to a pad 520, which is typically VSS ground. A drain 522 of the NMOS 506 is tied to the source of the NMOS 508, while the drain of the NMOS 508 is connected to the source of the NMOS 512 as well as an output pad 524 of the IC circuitry. The drain of the NMOS 512 is also tied to the output pad 524. The gate of the NMOS 512 is left floating to provide a stronger protection for the NMOS 508. It is further understood that another variation is to have the gate of NMOS 508 be tied with pad 524, and the function of this circuit is not compromised.

The cross-sectional view 504 shows the parasitic equivalent of the NMOSs 506, 508 and 512. Both the drain 522 and the source 516 of the NMOS 506 are represented by N+ diffusions. The P-type substrate 518, the source 516, and the gate 514 are all tied to metal leading to the pad 520, or VSS ground. At the gate 514 of the NMOS 506, there is a channel region 526 that is set between the N+ diffusions of the drain 522 and the source 516. This channel region 526 also conducts the drain-source current, thereby dissipating ESD charges during an ESD event. The collector of a parasitic lateral NPN transistor 528 is shown to be connected to the drain 522 of the NMOS 506, the drain of the NMOS 508, and the drain of the NMOS 512, while the emitter of the parasitic lateral NPN transistor 528 is connected to the source 516 of the NMOS 506. The base of the parasitic lateral NPN transistor 528 is connected to the P-type substrate 518 through a substrate resistance 530. The NMOS 508 has its gate tied directly to the pad 510, thereby providing extra resistance for the NMOS 506, while the NMOS 512 is left floating with the gate unconnected. The drain and source of the NMOS 512 are connected to the output pad 524, which is connected to the IC.

During normal operation of the IC, source supply applies power to the output pad 524. As such, the voltage at the output pad 524 is permitted to vary between VDD and VSS. Since the gate 514 of the NMOS 506 is grounded, the NMOS 506 will remain off. This allows normal operation for the IC since the output pad 524 is free to respond to normal circuit conditions.

When an ESD event occurs, the incoming voltage at the output pad 524 will be significantly higher than VDD with respect to VSS. The NMOSs 508 and 512 will protect the NMOS 506 by acting as extra resistance devices, thereby providing higher voltage tolerance to limit the current going into the PN junctions at the drain 522 of the NMOS 506. By having the NMOSs 508 and 512 taking a share of the heat created from the ESD pulses, the NMOS 506 may operate normally during the ESD event. The NMOS 512 will also act as an ESD implant layer to compensate the base widening issue, since the pad 510 will be floating during the ESD event. The high voltage of ESD pulses at the output pad 524 will cause the drain-source voltage of the NMOS 506 to increase rapidly above normal operating voltage. The reverse bias voltage on the PN junction formed between the drain 522 and the P-type substrate 518 will be increased by the large voltage at the drain 522 of the NMOS 506. When the reverse bias voltage reaches a point where the reverse bias junction undergoes a breakdown, current will flow between the drain 522 and the source 516. This will cause the PN junction between the channel region 526 and the source 516 to become forward biased, thereby forcing the parasitic lateral NPN transistor 528 to conduct. The NMOS 506 dissipates ESD current to the pad 520 before harmful charges build up to damage the IC.

With two extra transistors implemented, a larger voltage drop is achieved, thereby allowing a higher supply voltage to be used.

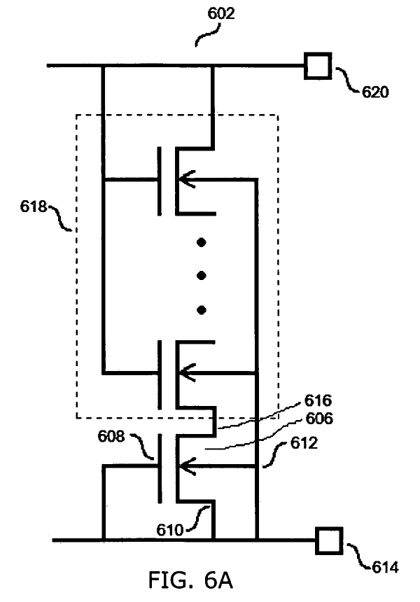

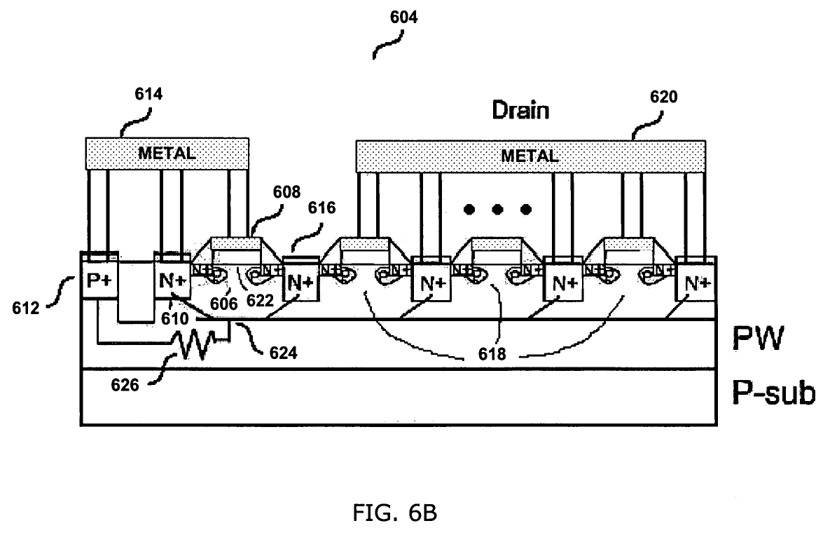

FIGS. 6A and 6B illustrate a grounded-gate NMOS transistor ESD protection circuit 602 and a cross-sectional view 604, respectively, in accordance with the fourth embodiment of the present invention. The protection circuit 602 demonstrates that a plurality of gates can be connected to the drain side of a grounded-gate, silicided NMOS 606 to improve ESD performance of a fully silicided process. A gate 608, a source 610, and a P-type substrate 612 of the NMOS 606 are all tied to a pad 614, which is typically VSS ground. A drain 616 of the NMOS 606 is connected to a series 618 of additional NMOS transistors, where all gates are tied directly to an output pad 620, which is connected to the IC. The series 618 of additional NMOS transistors protect the NMOS 606 by collectively acting as a silicide blocking layer to provide resistance to limit current from reaching the NMOS 606. This structure can provide protection even if the gate of the transistor 608 is not grounded.

The cross-sectional view 604 shows the parasitic equivalent of the NMOS 606 and the series 618. Both the drain 616 and the source 610 of the NMOS 606 are represented by N+ diffusions. The P-type substrate 612, the source 610, and the gate 608 are all tied to metal leading to the pad 614, or VSS ground. At the gate 608 of the NMOS 606, there is a channel region 622 that is set between the N+ diffusions of the drain 616 and the source 610. This channel region 622 conducts the drain-source current during an ESD event. The collector of a parasitic lateral NPN transistor 624 is shown to be connected to the drain 616 of the NMOS 606 and the drains of the NMOS transistors in the series 618, while the emitter is connected to the source 610 of the NMOS 606. The base of the parasitic lateral NPN transistor 624 is connected to the P-type substrate 612 through a substrate resistance 626. The NMOS transistors in the series 618 have their gates and drains all tied directly to the output pad 620, thereby collectively acting as a silicide blocking layer to provide some resistance for the NMOS 606 to protect it from harmful ESD pulses during an ESD event. It is understood that more than one transistor can be used in a series for performing the function of an RPO and more than one transistor can also be arranged in series to provide N+/P− junction for replacing ESD implants.

When the IC is in normal operation, source supply applies power to the output pad 620. As such, the voltage at the output pad 620 is permitted to vary between VDD and VSS. Since the gate 608 of the NMOS 606 is grounded, the NMOS 606 will remain off. This allows normal operation for the IC since the output pad 620 is free to respond to normal circuit conditions.

During an ESD event, as ESD enters the protection circuit 602, the incoming voltage at the output pad 620 will be significantly higher than VDD with respect to VSS. The NMOS transistors in the series 618 will protect the NMOS 606 by providing resistance to limit the current going through the channel of the NMOS 606. By having NMOS transistors in the series 618 taking a portion of the heat created from the ESD pulses, the NMOS 606 may operate normally during the ESD event. The high voltage at the output pad 620 will cause the drain-source voltage of the NMOS 606 to increase rapidly above normal operating voltage. The reverse bias voltage on the PN junction formed between the drain 616 and the substrate 612 will be increased by the large voltage at the drain 616 of the NMOS 606. When the reverse bias voltage reaches a point where the reverse bias junction undergoes a breakdown, current will flow between the drain 616 and the source 610. The NMOS 606 therefore dissipates ESD current to the pad 614, or VSS ground, before harmful charges build up to damage the IC.

This invention introduces methods and circuits to improve the ESD performance on fully silicided processing by implementing additional transistors to act as silicide blocking layers to provide extra resistance as protection to the ESD protection transistor. Embodiments shown in FIGS. 3A and 3B use additional NMOS transistors to replace the function of a resistor protection oxide (RPO) and provides a N+/P− junction for directing the ESD current, which removes the need of ESD implants using additional masks. Embodiments in FIGS. 4A, 4B, 5A and 5B use both thin and oxide devices in a cascode structure for maximizing the ESD protection. For example, the circuit in FIG. 5A uses transistor 508 as the RPO, and uses the transistor 512 to provide the function of the regular ESD implant. This circuit can be used for high voltage circuits while still using the thin oxide device for the ESD implant. The circuit in FIG. 6A shows that multiple transistors can be connected in series to provided the function needed, and the number of these transistors involved can vary depending on the need of the design.

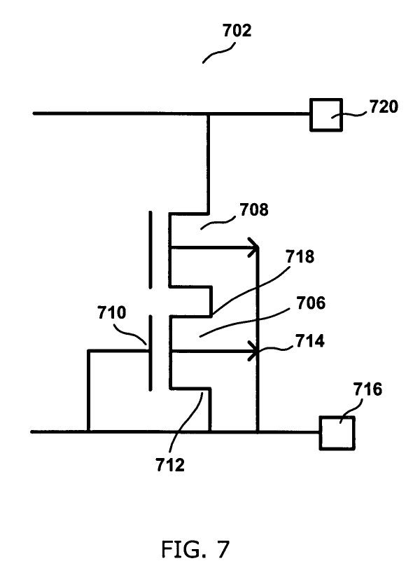

The extra transistors can share the heat that would have gathered at the PN junction of the ESD protection transistor. By implementing the additional transistors to act as silicide blocking layers, extra silicide blocking layer and ESD implant layer masks are not necessary. It is understood by those skilled in the art that PMOS transistors may also be used for ESD protection, and that the methods can be utilized in both thin and thick MOS transistors. In addition, the above embodiments illustrate the NMOS based ESD protection circuit between two pads, a circuit pad and a grounding pad. It is understood that equivalent PMOS based circuit elements may exist between a circuit pad and a power supply node such as the one 700 shown in FIG. 7. The function and operation of this circuit is the same as the NMOS based ESD protection circuit illustrated above. For example, the nodes 702 through 720 in FIG. 7 correspond to 402 through 420 in FIG. 4B. In this configuration, the PMOS ESD protection circuit is placed between a circuit pad 720 and a power supply pad (e.g., VDD) 716. Of course, the PMOS ESD protection circuits create N/P junction structures for directing the ESD current instead of the equivalent N/P junction structure in the NMOS ESD protection circuits. For the purpose of this invention, it is understood that the term “N/P” may refer to a junction structure which has a P portion and a N portion regardless of how these two are arranged, whether it is in NMOS ESD protection circuits or PMOS ESD protection circuits. For example, in the PMOS ESD protection circuit, the N/P junction is a P+/N− junction structure instead of the N+/P− structure in the NMOS configuration.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. An electro-static discharge (ESD) protection circuit coupled between a first and a second node for dissipating an ESD current, the circuit comprising:
at least one thin oxide transistor formed on a substrate and coupled to the first node for receiving the ESD current; and
at least one thick oxide transistor in series with the thin oxide transistor and with its gate coupled to the second node for dissipating the ESD current therethrough,
wherein the thin oxide transistor provides a N/P junction close to one of its diffusion regions for directing the ESD current through a parasitic transistor in the substrate and the thick oxide transistor.

2. The circuit of claim 1 wherein the thin oxide transistor has an low density drain (LDD) and a pocket region coupled thereto for providing a N+/P− junction.

3. The circuit of claim 1 wherein the thick oxide transistor has a low density drain and a pocket region coupled thereto for providing a N−/P− junction.

4. The circuit of claim 1 wherein both the thick and thin oxide transistors are NMOS transistors.

5. The circuit of claim 1 wherein both the thick and thin oxide transistors are PMOS transistors and the second node is a power supply.

6. The circuit of claim 1 wherein the thin oxide transistor has a floating gate.

7. The circuit of claim 1 further comprising at least one resistance spacer placed between the thick oxide and thin oxide transistors for providing a silicide blocking function.

8. The circuit of claim 7 wherein the resistance spacer is a blocking thick oxide transistor coupled in series with and placed between the thick oxide and thin oxide transistors.

9. The circuit of claim 8 wherein the blocking thick oxide is a high threshold voltage device when the ESD protection circuit is operating with a high voltage circuit.

10. An electro-static discharge (ESD) protection circuit coupled between a first and a second node for dissipating an ESD current, the circuit comprising:
a first transistor formed on a substrate with its gate and a first diffusion region coupled to the first node for receiving the ESD current; and
a second transistor coupled in series with the first transistor at its second diffusion region and with the second transistor's gate coupled to the second node for dissipating the ESD current therethrough,
wherein the first transistor provides a N/P junction close to its diffusion regions for directing the ESD current through a parasitic transistor in the substrate and the second transistor.

11. The circuit of claim 10 wherein the first transistor has a low density drain (LDD) and a pocket region coupled thereto for providing a N+/P− junction.

12. The circuit of claim 10 wherein the second transistor has a low density drain and a pocket region coupled thereto for providing a N−/P− junction.

13. The circuit of claim 10 wherein both the first and second transistors are NMOS transistors.

14. The circuit of claim 10 wherein both the first and second transistors are PMOS transistors and the second node is a power supply.

15. The circuit of claim 10 further comprising at least one resistor placed between the gate of the first transistor and the first node.

16. The circuit of claim 10 further comprising one or more additional transistors coupled in series with and placed between the first and second transistors, wherein gates thereof are coupled with the gate of the first transistor.

17. An electrostatic discharge (ESD) protection circuit coupled between a circuit pad and ground for dissipating an ESD current, the circuit comprising:
a first transistor formed on a substrate with a first diffusion region coupled to the circuit pad for receiving the ESD current; and
a second transistor coupled in series with the first transistor at its second diffusion region and with the second transistor's gate and one of its diffusion regions coupled to ground if the first and second transistors are NMOS transistors or a power supply if the first and second transistors are PMOS transistors for dissipating the ESD current therethrough,
wherein the first transistor provides a N/P junction for directing the ESD current through a parasitic transistor in the substrate and the second transistor, and
wherein a gate of the first transistor is either floating or coupled to the circuit pad.

18. The circuit of claim 17 wherein the first transistor has a low density drain (LDD) and a pocket region coupled thereto for providing the N/P junction, which is a N+/P− junction if the first transistor is a NMOS transistor.

19. The circuit of claim 18 wherein the second transistor has a low density drain and a pocket region coupled thereto for providing a N−/P− junction if it is a NMOS transistor.

20. The circuit of claim 17 wherein both the first and second transistors are NMOS transistors.

21. The circuit of claim 17 wherein both the first and second transistors are PMOS transistors.

22. The circuit of claim 17 wherein if the first transistor is a PMOS transistor, it has a low density drain (LDD) and a pocket region coupled thereto for providing the N/P junction, which is a P+/N− junction.

23. The circuit of claim 22 wherein if the second transistor is a PMOS transistor, it has a low density drain and a pocket region coupled thereto for providing a P−/N− junction.

24. The circuit of claim 17 further comprising at least one resistor placed between the gate of the first transistor and the circuit pad.

25. The circuit of claim 17 further comprising one or more additional transistors coupled in series with and placed between the first and second transistors, wherein gates thereof are coupled with the gate of the first transistor.

26. The circuit of claim 17 further comprising one or more blocking transistors coupled in series with and placed between the first and second transistors.

27. The circuit of claim 17 wherein the second transistor is a thick oxide transistor while the first transistor is a thin oxide transistor.

28. The circuit of claim 17 wherein both the first and second transistors are thick oxide transistors.
